(19) United States
(12) Patent Application Publication
(10) Pub. No.: US 2025/0155793 A1
(43) Pub. Date: May 15, 2025

(54) REFLECTIVE MASK BLANK FOR EUV LITHOGRAPHY, METHOD FOR MANUFACTURING SAME, REFLECTIVE MASK FOR EUV LITHOGRAPHY, AND METHOD FOR MANUFACTURING SAME

(71) Applicant: AGC Inc., Tokyo (JP)

(72) Inventors: Ryosuke SEI, Tokyo (JP); Keishi Tsukiyama, Tokyo (JP)

(73) Assignee: AGC Inc., Tokyo (JP)

(21) Appl. No.: 19/025,618

(22) Filed: Jan. 16, 2025

Related U.S. Application Data
(63) Continuation of application No. PCT/JP2023/027892, filed on Jul. 31, 2023.

(30) Foreign Application Priority Data
Aug. 9, 2022 (JP) 2022-126963

(51) Int. Cl. G03F 1/24; C23C 14/06; C23C 14/08; C23C 14/18; C23C 14/34

(52) U.S. Cl. CPC G03F 1/24; C23C 14/06; C23C 14/0641; C23C 14/0664; C23C 14/067; C23C 14/0676; C23C 14/083; C23C 14/18; C23C 14/3464

(57) ABSTRACT

A reflective mask blank for EUV lithography, comprising: a substrate; and a multilayer reflective film that reflects EUV light, and an absorption film that absorbs EUV light, which are stacked over the substrate in the stated order, wherein the absorption film comprises a metallic element X as a main component, the absorption film comprises a first crystal structure as a crystal structure of the metallic element X stable at normal pressure (1 atm) at 25° C. in a bulk state, and a second crystal structure different from the first crystal structure, and the peak area ratio of the second crystal structure is 9% or more.

### CROSS-REFERENCE TO RELATED PATENT APPLICATIONS

This application is a U.S. Bypass Continuation of International Patent Application No. PCT/JP2023/027892, filed on Jul. 31, 2023, which is based upon and claims the benefit to Japanese Patent Application No. 2022-126963, filed on Aug. 9, 2022. The contents of these applications are hereby incorporated by reference in their entireties.

### TECHNICAL FIELD

The present invention relates to reflective mask blanks for EUV lithography which are used for extreme ultraviolet (EUV) lithography in the manufacture of semiconductors or the like, and methods for producing the same, as well as reflective masks for EUV lithography using the reflective mask blanks for EUV lithography, and methods for producing the same.

### BACKGROUND ART

Conventionally, photolithography using visible or ultraviolet light has been employed in the semiconductor industry as a fine pattern transfer technique necessary for forming integrated circuits composed of fine patterns on Si substrates or the like. However, as semiconductor devices are increasingly miniaturized, conventional photolithography techniques will soon be unable to provide such miniaturization. The pattern resolution limit in photolithography is about one half of the exposure wavelength. The pattern resolution limit is said to be about one quarter of the exposure wavelength even when the immersion method is employed, and is expected to be about 20 nm to 30 nm even when the immersion method using ArF laser (193 nm) is employed. In this context, EUV lithography which is an exposure technique using EUV light having a wavelength shorter than that of ArF laser is regarded as a promising exposure technique at short wavelengths of 20 nm to 30 nm or higher. In the present specification, EUV light refers to light at wavelengths in the soft X-ray region or the vacuum ultraviolet region. Specifically, it refers to light at wavelengths of about 10 nm to 20 nm, in particular, about 13.5 nm±0.3 nm.

EUV light is easily absorbed in any substance, and the substance has a refractive index close to 1 at such wavelengths. Therefore, refractive optical systems such as conventional photolithography using visible or ultraviolet light cannot be used for EUV light. For this reason, reflective optical systems, specifically, reflective masks and mirrors are used in EUV lithography.

In reflective masks used in EUV lithography, mask patterns of absorption films that absorb EUV light are provided over multilayer reflective films that reflect EUV light at short wavelengths of about 13.5 nm. To increase the phase difference between the light reflected from a multilayer reflective film and the light reflected from an absorption film, the refractive index of the absorption film is preferably low, and the reflectivity of the absorption film is preferably controllable.

For example, Patent Literature 1 describes that phase shift masks can be obtained comprising absorption films which contain tantalum (Ta) and niobium (Nb) and of which the reflectivity is highly selective, by changing the composition ratio between Ta and Nb in such absorption films.

### CITATION LIST

### Patent Literature

PTL1: JP 2021-174003

### SUMMARY OF INVENTION

### Technical Problem

However, the absorption films described in Patent Literature 1 are made of alloy and must have a controlled alloy composition ratio, and also have a relatively high refractive index and must be formed as alloy films with a thickness of about 60 nm.

On the other hand, ruthenium (Ru) is an exemplary material having a low refractive index, and iridium (Ir) or the like having a higher absorption coefficient for EUV light may be used for changing the reflectivity, for example. However, when noble metal materials such as Ru and Ir are used as is, the line edge roughness (LER) which indicates the roughness of absorption film patterns becomes worse due to their excessively high crystallinity, making it difficult to form fine mask patterns required for reflective masks for EUV lithography.

The present invention has been achieved in view of such circumstances. An object of the present invention is to provide reflective mask blanks for EUV lithography that can allow preparation of reflective masks having absorption film patterns formed with good LERs by reducing the size of the crystallites of the absorption films, and methods for producing the same, as well as reflective masks for EUV lithography using the reflective mask blanks for EUV lithography, and methods for producing the same.

### Solution to Problem

As a result of extensive studies to achieve the above object, the present inventors have found that the object can be achieved by providing a crystal structure of absorption films of reflective mask blanks for EUV lithography which comprise a first crystal structure as a crystal structure of the metallic element X stable at normal pressure (1 atm) at 25° C. in a bulk state, and a second crystal structure different from the first crystal structure; and adjusting the peak area ratio of the second crystal structure to be 9% or more according to the X-ray diffraction (XRD) peak resolution method. This finding has led to the completion of the present invention.

Specifically, the present invention is as follows:

[1] A reflective mask blank for EUV lithography, comprising: a substrate; and a multilayer reflective film that reflects EUV light, and an absorption film that absorbs EUV light, which are stacked over the substrate in the stated order, wherein the absorption film comprises a metallic element X as a main component, the absorption film comprises a first crystal structure as a crystal structure of the metallic element X stable at normal pressure (1 atm) at 25° C. in a bulk state, and a second crystal structure different from the first crystal structure, and the peak area ratio of the second crystal structure (the peak area of the second crystal structure/(the peak area of the first crystal structure+the peak area of the second crystal structure)) is 9% or more, as calculated when resolving the XRD peaks having a peak top in the range of 30°≤2θ≤55° between the first crystal structure and the second crystal structure by the X-ray diffraction (XRD) peak resolution method using CuKα radiation as a radiation source.

[2] The reflective mask blank for EUV lithography according to [1] above, wherein the metallic element X is at least one selected from the group consisting of ruthenium (Ru), rhodium (Rh), palladium (Pd), silver (Ag), rhenium (Re), osmium (Os), iridium (Ir), platinum (Pt), and gold (Au).

[3] The reflective mask blank for EUV lithography according to [1] or [2] above, wherein the absorption film further comprises an element Z, and the element Z is at least one selected from the group consisting of hydrogen (H), boron (B), carbon (C), nitrogen (N), oxygen (O), chrome (Cr), niobium (Nb), molybdenum (Mo), hafnium (Hf), tantalum (Ta), and tungsten (W).

[4] The reflective mask blank for EUV lithography according to [2] above, wherein the absorption film comprises Ru as a main component, and the diffraction angle 2θ of the peak top in the range of 75°≤2θ≤90° is 84.5° or less in the X-ray diffraction (XRD) method using CuKα radiation as a radiation source.

[5] The reflective mask blank for EUV lithography according to any one of [1] to [4] above, wherein the first crystal structure is one of a face-centered cubic lattice (fcc) structure and a hexagonal close-packed (hcp) structure, and the second crystal structure is the other of the face-centered cubic lattice (fcc) structure and the hexagonal close-packed (hcp) structure.

[6] The reflective mask blank for EUV lithography according to [3] above, wherein the content of the metallic element X in the absorption film is 50 at % or more, and the content of the element Z in the absorption film is 50 at % or less.

[7] The reflective mask blank for EUV lithography according to any one of [1] to [6] above, wherein the film thickness of the absorption film is 60 nm or less.

[8] The reflective mask blank for EUV lithography according to any one of [1] to [7] above, wherein the reflective mask blank further comprises a protective film over the multilayer reflective film which protects the multilayer reflective film, and the protective film comprises at least one element selected from the group consisting of Ru, Rh, and silicon (Si).

[9] The reflective mask blank for EUV lithography according to any one of [1] to [8] above, wherein the reflective mask blank further comprises an etching mask film over the absorption film, and the etching mask film comprises at least one selected from the group consisting of aluminum (Al), Hf, yttrium (Y), Cr, Nb, titanium (Ti), Mo, Ta, and Si.

[10] The reflective mask blank for EUV lithography according to [9] above, wherein the etching mask film further comprises at least one selected from the group consisting of O, N, and B.

[11] A reflective mask for EUV lithography in which an opening pattern is formed on the absorption film of the reflective mask blank for EUV lithography according to any one of [1] to [10] above.

[12] A method for producing a reflective mask blank for EUV lithography, comprising: forming a multilayer reflective film over a substrate which reflects EUV light; and forming an absorption film over the multilayer reflective film which absorbs EUV light, wherein the absorption film comprises a metallic element X as a main component, the absorption film comprises a first crystal structure as a crystal structure of the metallic element X stable at normal pressure (1 atm) at 25° C. in a bulk state, and a second crystal structure different from the first crystal structure, and the peak area ratio of the second crystal structure (the peak area of the second crystal structure/(the peak area of the first crystal structure+the peak area of the second crystal structure)) is 9% or more, as calculated when resolving the XRD peaks having a peak top in the range of 30°≤2θ≤55° between the first crystal structure and the second crystal structure by the X-ray diffraction (XRD) peak resolution method using CuKα radiation as a radiation source.

[13] A method for producing a reflective mask for EUV lithography, comprising: forming an opening pattern by patterning an absorption film in a reflective mask blank for EUV lithography produced by the method for producing a reflective mask blank for EUV lithography according to [12] above.

### Advantageous Effects of Invention

The present invention can provide reflective mask blanks for EUV lithography that can allow preparation of reflective masks having absorption films patterned with low LERs by reducing the size of the crystallites of the absorption films, and methods for producing the same, as well as reflective masks for EUV lithography using the reflective mask blanks for EUV lithography, and methods for producing the same.

### BRIEF DESCRIPTION OF DRAWINGS

FIG. 1 is a schematic cross-sectional view showing an embodiment of the reflective mask blank for EUV lithography according to the present invention.

FIG. 2 is a schematic cross-sectional view showing another embodiment of the reflective mask blank for EUV lithography according to the present invention.

FIG. 3 is a schematic cross-sectional view showing an embodiment of the reflective mask for EUV lithography according to the present invention.

FIG. 4 is a view (1) showing a procedure of forming a pattern in the reflective mask blank for EUV lithography shown in FIG. 2.

FIG. 5 is a view (2) showing a procedure of forming a pattern in the reflective mask blank for EUV lithography shown in FIG. 2.

FIG. 6 is a view (3) showing a procedure of forming a pattern in the reflective mask blank for EUV lithography shown in FIG. 2.

FIG. 7 is a view (4) showing a procedure of forming a pattern in the reflective mask blank for EUV lithography shown in FIG. 2.

FIG. 8 is a crystal lattice image (TEM image) of a sample in Examples.

FIG. 9 is an electronic diffraction pattern of a sample in Examples.

### DESCRIPTION OF EMBODIMENTS

The definitions and meanings of terms and expressions in the present specification will be provided below.

The expression “comprises a metallic element X as a main component” refers to the fact that “the content of the metallic element X in the absorption film is 50 at % or more”. This is provided that the term “a metallic element X” refers not only to a single element but also to multiple elements. Here, when multiple metallic elements X are present, the expression “comprises a metallic element X as a main component” refers to the fact that “the total content of the metallic elements X in the absorption film is 50 at % or more.” For example, the expression “comprises a metallic element X as a main component” also applies to the case where the components of an absorption film are 40 at % of ruthenium (Ru), 40 at % of iridium (Ir), and 20 at % of tantalum (Ta), because the total content of ruthenium (Ru) (40 at %) and iridium (Ir) (40 at %), which are metallic elements X, is 80 at %.

The term “over the substrate”, “over the layer”, or “over the film” (hereinafter abbreviated as “over the film or the like”) refers not only to “in contact with the upper surface of the film or the like” but also to “above and not in contact with the upper surface of the film or the like.” For example, when the term “the film B over the film A” is used, the film A may be in contact with the film B, or another film or the like may be present between the film A and the film B. The term “over” herein does not necessarily mean that the position is vertically higher, and relates to a relative relationship between positions.

The refractive index is a value obtained from thickness-weighted average of the refractive indices of the respective films.

The term “sputter etching” refers to physical etching by accelerating ions, neutral particles or the like generated from etching gas by discharge plasma or the like, causing them to collide with a material to be etched, and throwing off particles of the material to be etched (sputtering), and such etching is not based on chemical reaction. By contrast, the term “chemical dry etching” refers to chemical etching mainly due to etching gas causing chemical reaction on the surface of a material to be etched and generating a reaction product with the material to be etched. Such etching may be accompanied by sputtering assistance from ions or the like, but is distinguished from physical etching in that reaction products volatile and labile are generated by chemical reaction. Reaction products can be volatile and labile in terms of the boiling point, for example, when the boiling point is 400° C. or less. The boiling point is a value at normal pressure (1 atm).

The thickness of the deposited film or the like is a value measured by X-ray reflectometry.

### [Reflective Mask Blank for EUV Lithography]

Embodiments of the present invention will be described below with reference to the drawings.

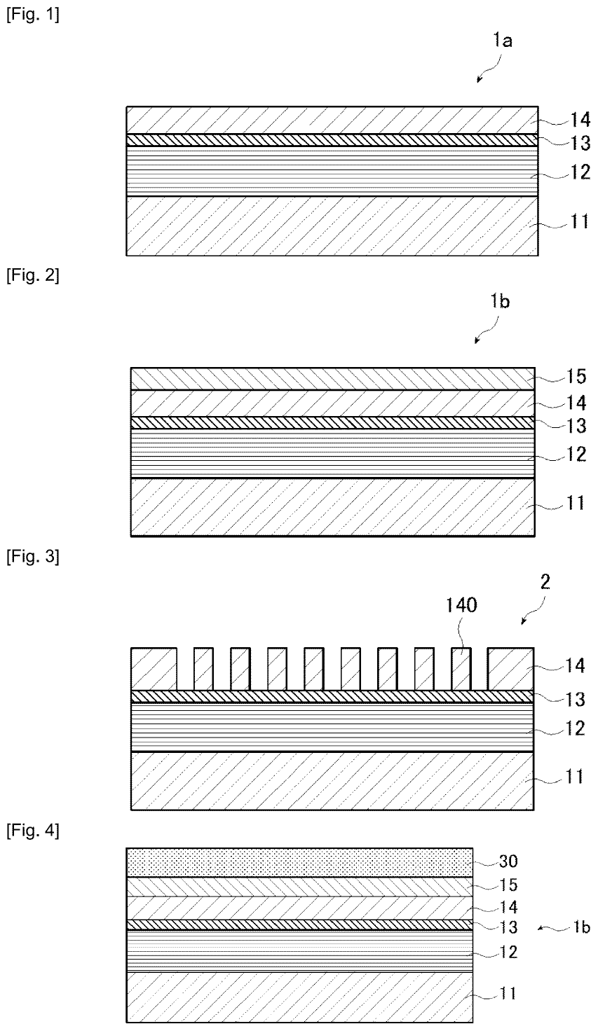

FIG. 1 is a schematic cross-sectional view showing an embodiment of the reflective mask blank for EUV lithography according to the present invention.

In the reflective mask blank 1a for EUV lithography shown in FIG. 1, a multilayer reflective film 12 that reflects EUV light, a protective film 13 (also called capping layer) to protect the multilayer reflective film 12 from etching during formation of a mask pattern, and an absorption film 14 that absorbs EUV light are stacked over the substrate 1 in the stated order. This is provided that, in the reflective mask blank for EUV lithography according to an embodiment of the present invention, in the configuration shown in FIG. 1, only the substrate 11, the multilayer reflective film 12, and the absorption film 14 are essential constituents, and the protective film 13 is an optional constituent.

In the reflective mask blank for EUV lithography according to the present invention, an antireflection film (not shown) may also be formed over the absorption film 14 to facilitate pattern defect inspection after mask processing.

In the reflective mask blank for EUV lithography according to the present invention, a buffer layer (not shown) may also be formed between the protective film 13 and the absorption film 14 to protect the multilayer reflective film 12 during dry etching or defect correction.

Moreover, in the reflective mask blank for EUV lithography according to the present invention, the multilayer reflective film 12 that reflects EUV light, the protective film 13 to protect the multilayer reflective film 12 from etching during formation of a mask pattern, the absorption film 14 that absorbs EUV light, and an etching mask film 15 composed of a material resistant to etching conditions for the absorption film 14 may be formed over the substrate 11 in the stated order, as in the reflective mask blank 1b for EUV lithography shown in FIG. 2.

Respective constituents of the reflective mask blank 1a, 1b for EUV lithography will be described below.

### (Substrate)

The substrate 11 preferably has a low thermal expansion coefficient at 20° C. in order to prevent distortion of transferred patterns due to heat during EUV exposure, and the thermal expansion coefficient is preferably 0±0.050×10⁻⁷/° C., more preferably 0±0.030×10⁻⁷/° C., and still more preferably 0±0.025×10⁻⁷/° C. Also preferably, the substrate 11 has high resistance to cleaning solutions used in the process of producing reflective masks for EUV lithography (chemical resistance).

Suitable examples of materials for the substrate 11 include SiO₂—TiO₂ glass and multicomponent glass ceramics. Crystallized glass in which β-quartz solid solutions are precipitated, quartz glass, silicon, metals, and the like may also be used as materials for the substrate 11.

The substrate 11 preferably has high smoothness in order to enable pattern transfer with high reflectivity and precision, and the root mean square roughness Rq is preferably 0.15 nm or less, more preferably 0.10 nm or less, and still more preferably 0.05 nm or less.

The substrate 11 preferably has a total indicated reading (TIR) of 100 nm or less, more preferably 50 nm or less, and still more preferably 30 nm or less, in order to enable pattern transfer with high reflectivity and precision.

The root mean square roughness Rq of the substrate 11 can be measured by the method shown in Examples.

The substrate 11 preferably has high rigidity in order to prevent deformation caused by stress from films or the like stacked thereover, and the Young's modulus is preferably 50 GPa or more, more preferably 60 GPa or more, and still more preferably 65 GPa or more.

The size, the thickness, and the like of the substrate 11 are appropriately determined according to the design values or the like for the mask. SiO₂—TiO₂ glass having a 6 inch (152 nm) square outer shape and a thickness of 0.25 inch (6.3 mm) was used in Examples provided below.

The substrate 11 preferably has no defects on the surface on which the multilayer reflective film 12 is formed. However, such defects are allowed unless phase defects due to concave and/or convex defects occur. Specifically, the depth of concave defects and the height of convex defects on the surface of the substrate 11 on which the multilayer reflective film 12 is formed are preferably 2 nm or less, more preferably 1 nm or less, and still more preferably 0.5 nm or less, and the half width of such concave and convex defects is preferably 60 nm or less, more preferably 30 nm or less, and still more preferably 15 nm or less. The half width of concave defects refers to the width at a position half of the depth of concave defects. The half width of convex defects refers to the width at a position half of the height of convex defects.

### (Multilayer Reflective Film)

The multilayer reflective film 12 preferably has a configuration in which multiple layers containing elements differing in refractive index as main components are periodically stacked, in order to increase the reflectivity of EUV light. The thickness of each film constituting the multilayer reflective film 12 and the cycle of repeating stacking of films are properly set according to the film materials, the desired reflectivity of EUV light, and the like. Generally, the multilayer reflective film 12 has a structure in which each pair of one higher refractive index layer and one lower refractive index layer is periodically stacked about 30 to 60 times.

Higher/lower refractive index layers are generally Mo/Si multilayer reflective films, but are not limited thereto. Examples of such layers include Ru/Si multilayer reflective films, Mo/Be multilayer reflective films, Mo compound/Si compound multilayer reflective films, Si/Mo/Ru multilayer reflective films, Si/Mo/Ru/Mo multilayer reflective films, Si/Ru/Mo multilayer reflective films, and Si/Ru/Mo/Ru multilayer reflective films.

In the multilayer reflective film 12, the reflectivity of an incident light of EUV light at a wavelength of about 13.5 nm at an incidence angle of 6° is preferably 60% or more, more preferably 62% or more, and still more preferably 65% or more. When the protective film 13 is provided over the multilayer reflective film 12, the maximum reflectivity of light at a wavelength of about 13.5 nm is also preferably 60% or more, more preferably 62% or more, and still more preferably 65% or more.

The multilayer reflective film 12 can be formed by depositing each constituent film to a desired thickness using known deposition methods such as magnetron sputtering and ion beam sputtering, for example.

For example, when an Mo/Si multilayer reflective film is formed by ion beam sputtering, an Si film is first deposited to a thickness of 4.5 nm using an Si target and an Mo film is then deposited to a thickness of 2.3 nm using an Mo target, at an ion acceleration voltage of 300 to 1500 V and a deposition rate of 0.030 to 0.300 nm/see using argon (Ar) gas (gas pressure: 1.3×10⁻² to 2.7×10⁻² Pa) as sputtering gas. Defining this as one cycle, the Mo/Si multilayer reflective film can be formed by stacking Mo/Si films by repeating the deposition for 30 to 60 cycles.

### (Protective Film)

The protective film 13 may be formed on the uppermost surface of the multilayer reflective film 12. The protective film 13 is provided in order to protect the multilayer reflective film 12 from damage by an etching process, usually a dry etching process, when a pattern is formed in the later-described absorption film 14 by the etching process.

Accordingly, preferably selected as a material for the protective film is a substance which is hardly affected by the etching process for the absorption film 14, in other words, a substance which is etched slower than the absorption film 14 and is hardly damaged by the etching process.

The protective film 13 is also provided in order to prevent oxidation of the multilayer reflective film 12 during EUV exposure, resulting in decreased reflectivity of EUV light.

The protective film 13 preferably contains at least one element selected from the group consisting of Ru, Pd, Ir, Rh, Pt, zirconium (Zr), Nb, Ta, Ti, and Si, and more preferably contains at least one element selected from the group consisting of Ru, Rh, and Si, to exhibit the above characteristics. However, since Ru is also a constituent material for the absorption film 14, Ru used as a material for the protective film 13 is preferably an alloy with another element such as RuZr. The protective film 13 may be either a single layer or two or more stacked layers.

The protective film 13, when containing Rh, may contain either Rh element exclusively or an Rh compound. The Rh compound may contain at least one element selected from the group consisting of Ru, Nb, Mo, Ta, Ir, Pd, Zr, Y, and Ti, in addition to Rh.

Addition of Ru, Nb, Mo, Zr, Y, or Ti to Rh can reduce the extinction coefficient and improve the reflectivity of EUV light while suppressing an increase in the refractive index. Also, addition of Ru, Ta, Ir, Pd, or Y to Rh can improve resistance to etching gas and sulfuric acid-hydrogen peroxide mixture. The sulfuric acid-hydrogen peroxide mixture is used for removing resist films or cleaning reflective masks, for example.

The protective film 13 may further contain at least one element selected from the group consisting of O, N, and B. In other words, it may contain oxides, nitrides, acid nitrides, or borides of the above elements. Specific examples include ZrO₂ and SiO₂.

When the protective film 13 is two or more stacked layers, at least one layer constituting the protective film 13 should be formed by Rh or an Rh compound. The protective film 13 may have a layer not containing Rh.

Preferably, the protective film 13 has a thickness of 1.5 nm or more and 4.0 nm or less, and more preferably 2.0 nm or more and 3.5 nm or less. The protective film 13 has high etching resistance when it has a thickness of 1.5 nm or more. The protective film 13 can suppress a decrease in the reflectivity of EUV light when it has a thickness of 4.0 nm or less.

Preferably, the protective film 13 has a density of 10.0 g/cm³ or more and 14.0 g/cm³ or less. The protective film 13 has high etching resistance when it has a density of 10.0 g/cm³ or more. The protective film 13 can suppress a decrease in the reflectivity of EUV light when it has a density of 14.0 g/cm³ or less.

Preferably, the upper surface of the protective film 13, specifically, the surface of the protective film 13 on which the absorption film 14 is formed has a root mean square roughness (Rq) of 0.300 nm or less, and more preferably 0.150 nm or less. The absorption film 14 or the like can be smoothly formed over the protective film 13 when the root mean square roughness (Rq) is 0.300 nm or less. Also, the diffraction of EUV light can be suppressed, and the reflectivity of EUV light can be improved. Preferably, the upper surface of the protective film 13, specifically, the surface of the protective film 13 on which the absorption film 14 is formed has a root mean square roughness (Rq) of 0.050 nm or more.

The protective film 13 can be deposited using known deposition methods such as magnetron sputtering and ion beam sputtering. For example, when an RuZr film is formed using DC sputtering, the film is preferably deposited to a thickness of 2 to 3 nm using a Ru target and a Zr target as targets and Ar gas (gas pressure: 1.0×10⁻² to 1.0×10⁰ Pa) as sputtering gas at an input power to the Ru target and the Zr target of 100 W or more and 600 W or less each at a deposition rate of 0.020 to 1.000 nm/sec.

### (Absorption Film)

The absorption film 14 may be a binary film that sufficiently absorbs incident EUV light, or a phase shift film that shifts a part of incident EUV light to a desired phase and reflects it, for example. Among such films, a phase shift film that shifts a part of incident EUV light to a desired phase and reflects it is preferable in order to improve the contrast of the transferred pattern.

The absorption film 14 contains a metallic element X as a main component and has a first crystal structure as a crystal structure of the metallic element X stable at normal pressure (1 atm) at 25° C. in a bulk state, and a second crystal structure different from the first crystal structure.

Here, preferably, the first crystal structure is one of a face-centered cubic lattice (fcc) structure and a hexagonal close-packed (hcp) structure, and the second crystal structure is the other of the face-centered cubic lattice (fcc) structure and the hexagonal close-packed (hcp) structure.

Because the absorption film 14 has a first crystal structure as a crystal structure of the metallic element X stable at normal pressure (1 atm) at 25° C. in a bulk state, and a second crystal structure different from the first crystal structure, the first crystal structure stable as bulk crystals is present together with the metastable second crystal structure not stable as bulk crystals.

The peak area ratio of the second crystal structure is not particularly limited only if it is 9% or more, but is preferably higher in order to prevent a decrease in the crystallinity of the absorption film 14. The peak area ratio is more preferably 12% or more, still more preferably 16% or more, and particularly preferably 20% or more.

The peak area ratio of the second crystal structure is calculated when resolving the XRD peaks having a peak top in the range of 30°≤2θ≤55° between the first crystal structure and the second crystal structure by the X-ray diffraction (XRD) peak resolution method using CuKα radiation as a radiation source, and is determined by dividing the peak area of the second crystal structure by the peak area of the first crystal structure and the peak area of the second crystal structure in total. Peak resolution based on the above peak resolution method is specifically performed by the method provided in Examples described later.

The peak area ratio of the second crystal structure can be controlled or adjusted to 9% or more by appropriately selecting the type and content of the metallic element X, the type and content of the element Z described later, and the method of forming the absorption film (the type of the formation method, the type of the atmosphere, the input power density per target area, etc.).

The metallic element X is not particularly limited, but is preferably a material having a low refractive index n in order to ensure the desired phase difference while suppressing the shadowing effect, and is preferably Ru, Rh, Pd, Ag, Re, Os, Ir, Pt, or Au. Among such elements, Ru, Rh, Ir, and Pt are more preferable, and Ru, Ir, and Pt are particularly preferable, in view of chemical resistance or the like during processing of the absorption film. Materials having a high extinction coefficient k are particularly preferable, and Ir and Pt are more particularly preferable, in order to suppress reflection from the absorption film and improve the transfer resolution. These elements may be used singly (as single elements) or in a combination of two or more. When two or more of the metallic elements are used, the two or more metallic elements may form an alloy.

When the two or more metallic elements X form an alloy, the first crystal structure as a crystal structure stable at normal pressure (1 atm) at 25° C. in a bulk state is distinguished from the second crystal structure which is a metastable crystal structure that is different from the first crystal structure and is not stable at normal pressure (1 atm) at 25° C. in a bulk state according to the phase diagram.

The content of the metallic element X in the absorption film 14 is not particularly limited, but is preferably 50 at % or more, more preferably 60 at % or more, and still more preferably 70 at % or more so that the absorption film 14 has optical properties (refractive index n and extinction coefficient k) suitable for providing the desired phase difference.

In the absorption film 14 in which the metallic element X is any of Ru, Re, and Os, the first crystal structure as a crystal structure stable at normal pressure (1 atm) at 25° C. in a bulk state is a hexagonal close-packed (hcp) structure, and the metastable second crystal structure not stable at normal pressure (1 atm) at 25° C. in a bulk state is a face-centered cubic lattice (fcc) structure. On the other hand, in the absorption film 14 in which the metallic element X is any of Rh, Pd, Ag, Ir, Pt, and Au, the first crystal structure as a crystal structure stable at normal pressure (1 atm) at 25° C. in a bulk state is a face-centered cubic lattice (fcc) structure, and the metastable second crystal structure not stable at normal pressure (1 atm) at 25° C. in a bulk state is a hexagonal close-packed (hcp) structure.

Preferably, the absorption film 14 further contains an element Z.

The element Z is not particularly limited, but is preferably H, B, C, N, O, Cr, Nb, Mo, Hf, Ta, or W, more preferably H, B, C, N, O, Cr, Hf, Ta, or W, still more preferably H, B, C, N, O, Cr, Ta, or W, and particularly preferably B, C, N, O, Cr, Ta, or W, in order to reduce the size of the crystallite. These elements may be used singly (as single elements) or in a combination of two or more.

The content of the element Z in the absorption film 14 is not particularly limited, but is preferably 50 at % or less, more preferably 40 at % or less, and still more preferably 30 at % or less so that the absorption film 14 has optical properties (refractive index n and extinction coefficient k) suitable for providing the desired phase difference.

When the metallic element X is Ru and the element Z is Ta, the ratio of the Ru content (at %) to the Ta content (at %) (Ru/Ta) is 30 to 80, for example. If the ratio of the Ru content to the Ta content (Ru/Ta) is 30 or more, the absorption film 14 can have improved hydrogen resistance. If the ratio of the Ru content to the Ta content (Ru/Ta) is 80 or less, the first selection ratio is high and the absorption film 14 has high processability. The ratio of the Ru content to the Ta content (Ru/Ta) is preferably 30 to 80, more preferably 30 to 70, and still more preferably 30 to 60.

When the metallic element X is Ru and the element Z is Cr, the ratio of the Ru content (at %) to the Cr content (at %) (Ru/Cr) is 1 to 15, for example. If the ratio of the Ru content to the Cr content (Ru/Cr) is 1 or more, the absorption film 14 can have improved hydrogen resistance. If the ratio of the Ru content to the Cr content (Ru/Cr) is 15 or less, the first selection ratio is high and the absorption film 14 has high processability. The ratio of the Ru content to the Cr content (Ru/Cr) is preferably 1 to 15, more preferably 2 to 12, still more preferably 3 to 10, and particularly preferably 4 to 8.

When the metallic element X is Ir and the element Z is Ta, the ratio of the Ir content (at %) to the Ta content (at %) (Ir/Ta) is 1 to 35, for example. If the ratio of the Ir content to the Ta content (Ir/Ta) is 1 or more, the absorption film 14 can have improved hydrogen resistance. If the ratio of the Ir content to the Ta content (Ir/Ta) is 35 or less, the first selection ratio is high and the absorption film 14 has high processability. The ratio of the Ir content to the Ta content (Ir/Ta) is preferably 1 to 35, more preferably 1 to 30, still more preferably 1 to 20, particularly preferably 1 to 15, and most preferably 2 to 10.

The film thickness of the absorption film 14 is not particularly limited, but is preferably 60 nm or less, more preferably 55 nm or less, and still more preferably 50 nm or less in order to suppress the shadowing effect (also sometimes called projection effect), and is preferably 10 nm or more, and more preferably 15 nm or more in order to provide the desired phase difference.

When the absorption film 14 contains Ru as a main component, the diffraction angle 2θ of the peak top in the range of 75°≤2θ≤90° is preferably 84.5° or less, more preferably 80.0° to 84.0°, and still more preferably 81.0° to 84.0° in the X-ray diffraction (XRD) method using CuKα radiation as a radiation source, from the viewpoint of a decrease in the crystallinity.

A layer under the absorption film may further be provided between the absorption film 14 and the protective film 13. The layer under the absorption film is a layer formed in contact with the uppermost surface of the protective film 13. A part of incident EUV light can be adjusted to a desired phase by providing a two-layer structure of the absorption film 14 and the layer under the absorption film.

The absorption film 14 can be formed according to the following procedure using known deposition methods such as reactive sputtering, magnetron sputtering, and ion beam sputtering.

When the absorption film 14 is formed using reactive sputtering, the reactive sputtering can be performed using a target containing Ru or Ir in an atmosphere containing argon (Ar) gas, O₂ gas, and N₂ gas at an O₂ volume ratio of 0 to 30 vol % and an N₂ volume ratio of 0 to 50 vol %, for example.

Other conditions than above for the reactive sputtering can be as follows:
Gas pressure: 5×10⁻² to 1.0 Pa, preferably 1×10⁻¹ to 8×10⁻¹ Pa, more preferably 2×10⁻¹ to 4×10⁻¹ Pa;
Input power density per target area: 1.0 to 15.0 W/cm², preferably 3.0 to 12.0 W/cm², more preferably 4.0 to 10.0 W/cm²;
Deposition rate: 0.010 to 1.000 nm/sec, preferably 0.015 to 0.500 nm/sec, and more preferably 0.050 to 0.400 nm/sec.

In the present specification, the root mean square roughness Rq of the surface of the absorption film 14 measured using an atomic force microscope is used as an indicator of smoothness of the surface of the absorption film 14.

In the reflective mask blank 1a for EUV lithography according to an embodiment of the present invention, the root mean square roughness Rq of the surface of the absorption film 14 is preferably 0.50 nm or less, more preferably 0.45 nm or less, and still more preferably 0.40 nm or less.

The phase difference between the EUV light reflected from the multilayer reflective film 12 and the EUV light reflected from the absorption film 14 is preferably 150 to 250 degrees, more preferably 180 to 250 degrees, and still more preferably 200 to 250 degrees.

Use of half-tone reflective masks for EUV lithography is in principle a means effective to improve the resolution in EUV lithography. However, the optimal reflectivity in half-tone reflective masks for EUV lithography depends on the exposure conditions and the patterns to be transferred and can hardly be determined uniformly.

### (Antireflection Film)

An antireflection film (not shown) to prevent reflection is preferably stacked over the absorption film 14 when DUV light (deep ultraviolet light) at a wavelength of 190 to 260 nm is used in the inspection process.

Reflective masks for EUV lithography are inspected to determine whether or not defects are present in the mask pattern formed on the absorption film 14. In this mask inspection, light which transmits masks cannot be used as light for inspection and DUV light is used, because the presence or absence of defects or the like is determined mainly based on the optical data of the reflected light for inspection. Therefore, for accurate inspection, an antireflection film to prevent reflection of DUV light for inspection is preferably provided over the absorption film 14.

The antireflection film is preferably formed by a material having a refractive index for DUV light lower than that of the absorption film 14 in order to play the above-described role. Examples of the constituent materials for the antireflection film include materials containing Ta as a main component and one or more components other than Ta selected from the group consisting of Hf, Ge, Si, B, N, H, and O. Specific examples include TaO, TaON, TaONH, TaHfO, TaHfON, TaBSiO, and TaBSiON.

The antireflection film can be formed by depositing to a desired thickness using known deposition methods such as magnetron sputtering and ion beam sputtering, for example.

### (Buffer Layer)

The constituent material for the buffer layer is not particularly limited, examples of which include materials containing SiO₂, Cr, or Ta as a main component.

### (Etching Mask Film)

As generally known, resist films can be thinner by providing a layer of a material resistant to etching conditions for an absorption film (an etching mask film) over the absorption film. Specifically, resist films can be thinner by forming an etching mask film and making the relative ratio of the etching rate for the etching mask film to the etching rate for an absorption film under the etching conditions for the absorption film (etching selection ratio) lower than 1.

The etching mask film 15 is required to have a sufficiently high etching selection ratio under the etching conditions for the absorption film 14.

Therefore, the etching mask film 15 is required to have high etching resistance to dry etching using O₂ or a mixed gas of O₂ and halogen gas (chlorine gas, fluorine gas) as etching gas.

On the other hand, preferably, the etching mask film 15 can be removed with a cleaning solution using an acid or base which is employed as a cleaning solution for resist films in EUV lithography.

Specific examples of the cleaning solution used for the above purpose include sulfuric acid-hydrogen peroxide mixture (SPM), ammonia-hydrogen peroxide mixture, and hydrofluoric acid. SPM is a solution in which sulfuric acid and hydrogen peroxide are mixed, and sulfuric acid and hydrogen peroxide can be preferably mixed at a volume ratio of 4:1 to 1:3, and more preferably 3:1. Here, the temperature of SPM is preferably controlled to 100° C. or more in order to improve the etching rate.

Ammonia-hydrogen peroxide mixture is a solution in which ammonia and hydrogen peroxide are mixed, and NH₄OH, hydrogen peroxide, and water can be preferably mixed at a volume ratio of 1:1:5 to 3:1:5. Here, the temperature of ammonia-hydrogen peroxide mixture is preferably controlled to 70 to 80° C.

Preferably, the etching mask film 15 contains at least one element selected from the group consisting of Al, Hf, Y, Cr, Nb, Ti, Mo, Ta, and Si in order to meet the above demands. The etching mask film 15 may further contain at least one element selected from the group consisting of O, N, and B. In other words, it may contain oxides, acid nitrides, nitrides, or borides of the above elements.

Specific examples of the constituent materials for the etching mask film 15 include Al materials such as Al, Al₂O₃, and AlN; Hf materials such as Hf and HfO₂; Y materials such as Y and Y₂O₃; Cr materials such as Cr, Cr₂O₃, and CrN; Nb materials such as Nb, Nb₂O₅, and NbON; Mo materials such as Mo, MoO₃, and MOON; Ta materials such as Ta, Ta₂O₅, and TaON; and Si materials such as Si, SiO₂, and Si₃N₄.

The etching mask film 15 composed of an Nb or Mo material can be etched by dry etching using chlorine gas as etching gas.

The etching mask film 15 composed of an Si material can be etched by dry etching using fluorine gas as etching gas. Preferably, removal of the Si material used as the etching mask film 15 employs hydrofluoric acid as a cleaning solution.

The film thickness of the etching mask film 15 is preferably 20 nm or less in terms of removability using a cleaning solution. More preferably, the etching mask film 15 composed of an Nb material has a film thickness of 5 to 15 nm.

The etching mask film 15 can be formed by known deposition methods such as magnetron sputtering and ion beam sputtering, for example.

For example, when an NbN film is formed by sputtering, reactive sputtering can be performed using an Nb target in a gas atmosphere in which inert gas containing at least one of He, Ar, Ne, Kr, and Xe (hereinafter simply called “inert gas”) is mixed with oxygen. Specifically, magnetron sputtering can be performed under the following deposition conditions:
Sputtering gas: Mixed gas of Ar gas and N₂ (volume ratio of N₂ in the mixed gas (N₂/(Ar+N₂))=15 vol % or more);
Gas pressure: 5.0×10⁻² to 1.0 Pa, preferably 1.0×10⁻¹ to 8.0×10⁻¹ Pa, more preferably 2.0×10⁻¹ to 4.0×10⁻¹ Pa;
Input power density per target area: 1.0 to 15.0 W/cm², preferably 3.0 to 12.0 W/cm², more preferably 4.0 to 10.0 W/cm²;
Deposition rate: 0.010 to 1.0 nm/sec, preferably 0.015 to 0.50 nm/sec, and more preferably 0.020 to 0.30 nm/sec;
Distance between target and substrate: 50 to 500 mm, preferably 100 to 400 mm, more preferably 150 to 300 mm.

When other inert gas than Ar is used, the concentration of the inert gas is preferably in the same concentration range as the Ar gas concentration range described above. When multiple inert gases are used, the total concentration of the inert gases is preferably in the same concentration range as the Ar gas concentration range described above.

### (Other Configurations)

In the reflective mask blank 1a, 1b for EUV lithography according to the present embodiment, functional films known for reflective mask blanks for EUV lithography may be provided in addition to the respective films and layers described above.

For example, a back surface conductive film may be formed on the surface of the substrate 11 which is opposite to the multilayer reflective film 12 (back surface) side in order to attach and fix the reflective mask blank 10 for EUV lithography to an electrostatic chuck mounting part or the like.

The back surface conductive film preferably has a sheet resistance of 100Ω/□ or less and can have a known configuration. Examples of the constituent material for the back surface conductive film include Si, TiN, Mo, Cr, and TaSi. The back surface conductive film can have a thickness of 10 to 1000 nm, for example.

The back surface conductive film can be formed by depositing to a desired thickness using known deposition methods such as magnetron sputtering, ion beam sputtering, chemical vapor deposition (CVD), vacuum vapor deposition, and electroplating, for example.

### [Method for Producing Reflective Mask Blank for EUV Lithography]

The method for producing a reflective mask blank for EUV lithography according to an embodiment of the present invention is a method for producing a reflective mask blank for EUV lithography, comprising: forming a multilayer reflective film over a substrate which reflects EUV light; and forming an absorption film over the formed multilayer reflective film which absorbs EUV light, wherein the absorption film comprises a metallic element X as a main component, the absorption film comprises a first crystal structure as a crystal structure of the metallic element X stable at normal pressure (1 atm) at 25° C. in a bulk state, and a second crystal structure different from the first crystal structure, and the peak area ratio of the second crystal structure is 9% or more.

The method of forming the multilayer reflective film and the method of forming the absorption film are as described above.

### [Reflective Mask for EUV Lithography]

FIG. 3 is a schematic cross-sectional view showing an embodiment of the reflective mask for EUV lithography according to the present invention.

In the reflective mask 2 for EUV lithography shown in FIG. 3, a pattern (absorption film pattern) 140 is formed on the absorption film 14 of the reflective mask blank 1a for EUV lithography shown in FIG. 1. Specifically, the multilayer reflective film 12 that reflects EUV light, the protective film 13 for the multilayer reflective film 12, and the absorption film 14 that absorbs EUV light are formed over the substrate 11 in the stated order, and the pattern (absorption film pattern) 140 is formed on the absorption film 14.

Among the constituents of the reflective mask 2 for EUV lithography, the substrate 11, the multilayer reflective film 12, the protective film 13, and the absorption film 14 are the same as in the reflective mask blank 1a for EUV lithography as described above.

### [Method for Producing Reflective Mask for EUV Lithography]

In the method for producing a reflective mask for EUV lithography according to an embodiment of the present invention, the pattern (absorption film pattern) 140 is formed by patterning the absorption film 14 of the reflective mask blank 1b for EUV lithography produced by the method for producing a reflective mask blank for EUV lithography according to an embodiment of the present invention.

The procedure of forming the pattern on the absorption film 14 of the reflective mask blank 1b for EUV lithography will be described with reference to the drawings.

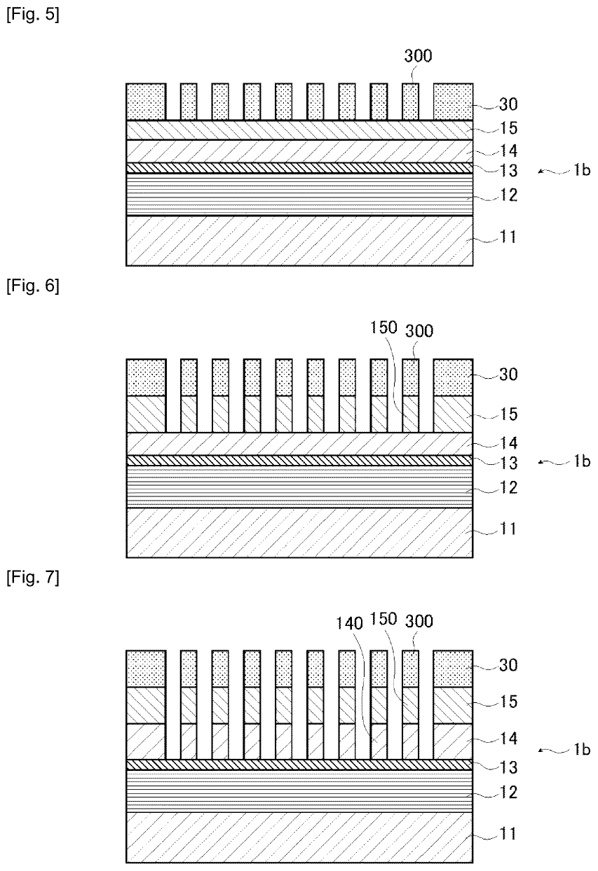

As shown in FIG. 4, a resist film 30 is formed over the etching mask film 15 of the reflective mask blank 1b for EUV lithography. Next, as shown in FIG. 5, a resist pattern 300 is formed on the resist film 30 using an electron beam drawer.

Next, as shown in FIG. 6, an etching mask film pattern 150 is formed on the etching mask film 15 using, as a mask, the resist film 30 on which the resist pattern 300 is formed.

Next, as shown in FIG. 7, the absorption film pattern 140 is formed on the absorption film 14 using, as a mask, the etching mask film 15 on which the etching mask film pattern 150 is formed.

Next, the reflective mask 2 for EUV lithography with the absorption film pattern 140 exposed is provided by removing the resist film 30 and the etching mask film 15 with a cleaning solution using an acid or base. Although most of the resist pattern 300 and the resist film 30 are removed in the course of forming the absorption film pattern 140, cleaning with a cleaning solution using an acid or base is performed in order to remove the remaining resist pattern 300, resist film 30, and etching mask film 15.

In the reflective mask for EUV lithography according to the present invention, a mask pattern is formed on the absorption film 14 of the reflective mask blank 1a, 1b for EUV lithography according to the present embodiment.

Lithography can be applied to the method for producing a reflective mask for EUV lithography according to the present invention, and etching is preferably performed through the etching process shown in FIGS. 3 to 7 mentioned above. Specifically, for the formation of a mask pattern on the reflective mask blank 1a, 1b for EUV lithography, it is preferable to treat the absorption film 14 of the reflective mask blank 1a, 1b for EUV lithography with sputter etching and then with chemical dry etching.

Mask patterns can be formed on reflective mask blanks for EUV lithography efficiently and precisely by producing reflective masks for EUV lithography by applying such an etching process using the reflective mask blank for EUV lithography according to the present embodiment.

Although various embodiments have been described above with reference to the drawings, the present invention is in no way limited to such embodiments. Those skilled in the art will obviously be able to arrive at various changes and modifications within the scope described in the claims, and they shall also naturally pertain to the technical scope of the present invention. Any combinations of the respective constituents in the above embodiments are possible without departing from the subject matter of the invention.

### EXAMPLES

The present invention will be specifically described below by way of examples; however, the present invention is not limited to the following examples and various variations are possible without departing from the subject matter of the present invention.

Among Examples 1 to 12, Examples 1 to 8 are working examples and Examples 9 to 12 are comparative examples.

### Examples 1 to 12

### (Preparation of Reflective Mask Blanks for EUV Lithography)

Reflective mask blanks for EUV lithography comprising a substrate, a multilayer reflective film, a protective film, and an absorption film in the stated order were prepared.

A SiO₂—TiO₂ glass substrate (outer shape: 6 inch (152 mm) square, thickness: 6.3 mm) was provided as a substrate. This glass substrate had a thermal expansion coefficient at 20° C. of 0.020×10⁻⁷/° C., a Young's modulus of 67 GPa, a Poisson's ratio of 0.17, and a specific rigidity of 3.07×10⁷ m²/s². The quality assurance area of the first main surface of the substrate had a root mean square roughness Rq of 0.150 nm or less and a flatness of 100 nm or less due to polishing. A 100 nm-thick Cr film was deposited on the second main surface of the substrate using magnetron sputtering. The Cr film had a sheet resistance of 100Ω/□.

The root mean square roughness Rq of the substrate was measured using an atomic force microscope according to JIS B 0601:2013.

An Mo/Si multilayer reflective film was formed as a multilayer reflective film. The Mo/Si multilayer reflective film was formed by repeating deposition of an Si film (film thickness: 4.5 nm) and an Mo film (film thickness: 2.3 nm) 40 times using ion beam sputtering. The total film thickness of the Mo/Si multilayer reflective film was 272 nm ((4.5 nm+2.3 nm)×40).

An Rh film (single layer, film thickness: 2.5 nm) was formed as a protective film using ion beam sputtering.

As absorption films, Ru-based absorption films were formed by the method provided in the following section “Ru-based absorption film” (Examples 1 to 4 and 9 to 11), and Ir-based absorption films were formed by the method provided in the following section “Ir-based absorption film” (Examples 5 to 8 and 12).

### <Ru-Based Absorption Film>

An absorption film was deposited under the following conditions (1) to (6) by reactive sputtering using an Ru target, a C target, a Ta target, and a Cr₃C₂ target with the Ar, O₂, and N₂ gas flow rates and the input power to each target adjusted so that the absorption film had a composition as shown in Table 1. DC power sources were used for each target.
(1) Input power: 100 to 800 W
(2) Gas pressure: 0.3 Pa
(3) O₂ gas volume ratio (O₂/(Ar+O₂+N₂)): 0 to 30 vol %
(4) N₂ gas volume ratio (N₂/(Ar+O₂+N₂)): 0 to 50 vol %
(5) Deposition rate: 0.050 to 0.400 nm/sec
(6) Film thickness: 35 nm

### <Ir-Based Absorption Film>

Reactive sputtering was performed using an Ir target, a Ta target, a Ta₆₀B₄₀ target, and a B target. A DC power source was used for sputtering of the Ir target, Ta target, or Ta₆₀B₄₀ target, and an RF power source was used for sputtering of the B target. Other conditions were the same as those for the Ru-based absorption film. Thus, an Ir-based absorption film was deposited.

The elementary compositions (at %) for the absorption films of Examples 1 to 12 were measured by X-ray photoelectron spectroscopy (XPS). The composition ratio between Ru and C in Example 3 was measured by energy dispersive X-ray spectroscopy (EDX), because peaks overlapped and were difficult to measure by XPS. B in Examples 5 to 7 and B and O in Example 8 could not be quantified by XPS due to them being outside the detection limit, but were confirmed to be contained in the films by secondary ion mass spectrometry (SIMS). The measured elementary compositions (at %) are shown in Table 1.

The film thickness of the absorption films of Examples 1 to 12 was measured to be 35 nm by X-ray reflectometry (XRR).

### (Measurement of Crystallite Size)

Crystallinity of the absorption films was measured using an X-ray diffraction analyzer (MiniFlex II) manufactured by Rigaku Corporation. The crystallite size was calculated using the Scherrer's equation for the full width at half maximum of the highest intensity peak in the range of 2θ=30° to 55°. The measured crystallite sizes are shown in Table 1.

### (Calculation of Peak Area Ratio, Calculation of XRD Peak Position)

The presence ratio of each crystal phase (first crystal structure, second crystal structure) of the absorption film was evaluated using the peak area of the crystal phase. The peak area ratio (%) of the second crystal structure calculated during peak resolution is shown in Table 1. Analysis software “Diffrac. TOPAS” manufactured by Bruker Corporation was used for peak resolution based on the peak resolution method. The profile function was determined by the FP method using instrument parameters. The background function was generated in the range of 2θ=30 to 75° using a quadratic polynomial. Among the diffraction patterns obtained from in-plane XRD measurement using an X-ray diffraction analyzer (D8 DISCOVER) manufactured by Bruker Corporation, peak resolution was performed for the range of 30 to 55° using peaks of two fcc structures ((111) and (200) planes) and of three hcp structures ((100), (002), and (101) planes). For peak resolution, the constraint conditions were set so that the crystallite size of each crystal phase was not less than 1.0 nm.

The XRD peak position of each crystal phase of the absorption film used for peak resolution was calculated based on the lattice constant obtained from the later-described TEM image analysis.

Table 1 shows the values of diffraction angles 2θ of the peak tops in the range of 75°≤2θ≤90° in the in-plane XRD measurement using an X-ray diffraction analyzer (D8 DISCOVER) manufactured by Bruker Corporation when the main component was Ru.

### (Measurement of TEM Image)

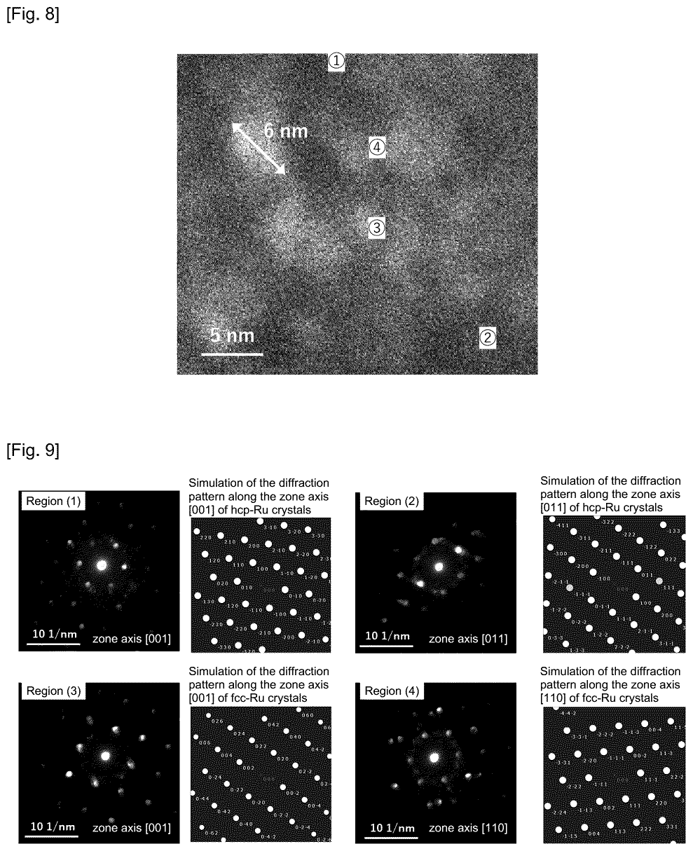

A TEM image was measured using the sample piece of Example 1 which was polished to a thickness of about 50 nm from both the absorption film surface side and the substrate side using the focused ion beam method. The sample piece was observed with TEM using NEOARM manufactured by JEOL Ltd. to acquire a crystal lattice image (TEM image) (FIG. 8) and an electronic diffraction pattern (FIG. 9) of the sample. FIG. 9 also shows the results of simulating electronic diffraction patterns using an hcp crystal structure of Ru (ICSD No. 76155) and a fcc crystal structure of Ru (ICSD No. 235808) as models of crystal structures.

Each bright area in FIG. 8 is assumed to correspond to one crystal grain, and the size of the representative crystal grain indicated by the arrow in FIG. 8 was 6 nm, which was almost in agreement with the crystallite size determined from the Scherrer's equation shown in Table 1.

The obtained crystal lattice image (TEM image) (FIG. 8) and electronic diffraction pattern (FIG. 9) were analyzed with analysis software “Digital MicroGraph” manufactured by Gatan, Inc. to derive the presence of the crystal structures (first crystal structure, second crystal structure) and the lattice constant of the sample.

The circles 1, 2, 3, and 4 in FIG. 8 correspond to the circles 1, 2, 3, and 4 in FIG. 9, respectively. The circles 1 and 2 represent areas in which the hcp crystal structure of Ru (first crystal structure) is dominant, and the circles 3 and 4 represent areas in which the fcc crystal structure of Ru (second crystal structure) is dominant.

TABLE 1

| | | | | | | | | | | | | | Peak area | XRD |
|---|---|---|---|---|---|---|---|---|---|---|---|---|---|---|
| | Type of | | | | | | | | | Crystallite | First | Second | ratio of | peak |
| | absorption | Composition of absorption film (at %) | | | | | | | | size | crystal | crystal | second crystal | position |
| | film | Ru | Ir | Cr | Ta | B | | CO | N | (nm) | structure | structure | structure (%) | (°) |
| Example 1 | RuTaON | 86.5 | — | — | 2.8 | — | — | 7.2 | 3.5 | 6.1 | hcp | fcc | 37 | 83.9 |
| Example 2 | RuTaON | 90.7 | — | — | 1.6 | — | — | 3.1 | 4.5 | 7.4 | hcp | fcc | 56 | 83.5 |
| Example 3 | RuCN | 88.6 | — | — | — | — | 9.8 | — | 1.5 | 5.4 | hcp | fcc | 75 | 82.6 |
| Example 4 | RuCrCN | 72.3 | — | 12.1 | — | — | 8.0 | — | 7.6 | 5.6 | hcp | fcc | 90 | 82.0 |
| Example 5 | IrTaB | — | 88.5 | — | 11.5 | <1.0 | — | — | — | 5.7 | fcc | hcp | 22 | — |
| Example 6 | IrTaB | — | 84.3 | — | 15.7 | <1.0 | — | — | — | 4.5 | fcc | hcp | 27 | — |
| Example 7 | IrTaB | — | 82.5 | — | 17.5 | <1.0 | — | — | — | 3.6 | fcc | hcp | 23 | — |
| Example 8 | IrTaBON | — | 87.0 | — | 11.4 | <1.0 | — | <1.0 | 1.6 | 6.2 | fcc | hcp | 12 | — |
| Example 9 | Ru | 100.0 | — | — | — | — | — | — | — | 21.2 | hcp | fcc | 0 | 85.0 |
| Example 10 | RUN | 98.5 | — | — | — | — | — | — | 1.5 | 11.7 | hcp | fcc | 8 | 84.6 |
| Example 11 | RuTaO | 88.6 | — | — | 3.2 | — | — | 8.2 | — | 12.5 | hcp | fcc | 1 | 85.0 |
| Example 12 | IrTaON | — | 91.3 | — | 2.5 | — | — | 4.3 | 1.9 | 8.9 | fcc | hcp | 8 | — |

As shown in Table 1, in Examples 1 to 8, since the peak area ratio of the second crystal structure was 12 to 90%, the crystallite size of the absorption film could be reduced, making it possible to prepare a reflective mask having a high LER after forming the pattern of the absorption film.

By contrast, in Examples 9 to 12, since the peak area ratio of the second crystal structure was 0 to 8%, the crystallite size of the absorption film could not be reduced, making it impossible to prepare a reflective mask having a high LER after forming the pattern of the absorption film.

### INDUSTRIAL APPLICABILITY

The reflective mask blank for EUV lithography, and the method for producing the same, as well as the reflective mask for EUV lithography using the reflective mask blank for EUV lithography, and the method for producing the same according to the present invention are suitably used for EUV lithography in the manufacture of semiconductors or the like.

### REFERENCE SIGNS LIST

1a, 1b: Reflective mask blank for EUV lithography
2: Reflective mask for EUV lithography
11: Substrate
12: Multilayer reflective film
13: Protective film
14: Absorption film
15: Etching mask film
30: Resist film
140: Absorption film pattern
150: Etching mask film pattern
300: Resist pattern

1. A reflective mask blank for EUV lithography, comprising: a substrate; and a multilayer reflective film that reflects EUV light, and an absorption film that absorbs EUV light, which are stacked over the substrate in the stated order,
wherein the absorption film comprises a metallic element X as a main component,
the absorption film comprises a first crystal structure as a crystal structure of the metallic element X stable at normal pressure (1 atm) at 25° C. in a bulk state, and a second crystal structure different from the first crystal structure, and
the peak area ratio of the second crystal structure (the peak area of the second crystal structure/(the peak area of the first crystal structure+the peak area of the second crystal structure)) is 9% or more, as calculated when resolving the XRD peaks having a peak top in the range of 30°≤2θ≤55° between the first crystal structure and the second crystal structure by the X-ray diffraction (XRD) peak resolution method using CuKα radiation as a radiation source.

2. The reflective mask blank for EUV lithography according to claim 1, wherein the metallic element X is at least one selected from the group consisting of ruthenium (Ru), rhodium (Rh), palladium (Pd), silver (Ag), rhenium (Re), osmium (Os), iridium (Ir), platinum (Pt), and gold (Au).

3. The reflective mask blank for EUV lithography according to claim 1,
wherein the absorption film further comprises an element Z, and
the element Z is at least one selected from the group consisting of hydrogen (H), boron (B), carbon (C), nitrogen (N), oxygen (O), chrome (Cr), niobium (Nb), molybdenum (Mo), hafnium (Hf), tantalum (Ta), and tungsten (W).

4. The reflective mask blank for EUV lithography according to claim 2,
wherein the absorption film comprises Ru as a main component, and
the diffraction angle 2θ of the peak top in the range of 75°≤2θ≤90° is 84.5° or less in the X-ray diffraction (XRD) method using CuKα radiation as a radiation source.

5. The reflective mask blank for EUV lithography according to claim 1, wherein the first crystal structure is one of a face-centered cubic lattice (fcc) structure and a hexagonal close-packed (hcp) structure, and the second crystal structure is the other of the face-centered cubic lattice (fcc) structure and the hexagonal close-packed (hcp) structure.

6. The reflective mask blank for EUV lithography according to claim 3,
wherein the content of the metallic element X in the absorption film is 50 at % or more, and
the content of the element Z in the absorption film is 50 at % or less.

7. The reflective mask blank for EUV lithography according to claim 1, wherein the film thickness of the absorption film is 60 nm or less.

8. The reflective mask blank for EUV lithography according to claim 1,
wherein the reflective mask blank further comprises a protective film over the multilayer reflective film which protects the multilayer reflective film, and
the protective film comprises at least one element selected from the group consisting of Ru, Rh, and silicon (Si).

9. The reflective mask blank for EUV lithography according to claim 1, wherein the reflective mask blank further comprises an etching mask film over the absorption film, and the etching mask film comprises at least one selected from the group consisting of aluminum (Al), Hf, yttrium (Y), Cr, Nb, titanium (Ti), Mo, Ta, and Si.

10. The reflective mask blank for EUV lithography according to claim 9, wherein the etching mask film further comprises at least one selected from the group consisting of O, N, and B.

11. A reflective mask for EUV lithography in which an opening pattern is formed on the absorption film of the reflective mask blank for EUV lithography according to claim 1.

12. A method for producing a reflective mask blank for EUV lithography, comprising:
forming a multilayer reflective film over a substrate which reflects EUV light; and
forming an absorption film over the multilayer reflective film which absorbs EUV light,
wherein the absorption film comprises a metallic element X as a main component,
the absorption film comprises a first crystal structure as a crystal structure of the metallic element X stable at normal pressure (1 atm) at 25° C. in a bulk state, and a second crystal structure different from the first crystal structure, and
the peak area ratio of the second crystal structure (the peak area of the second crystal structure/(the peak area of the first crystal structure+the peak area of the second crystal structure)) is 9% or more, as calculated when resolving the XRD peaks having a peak top in the range of 30°≤2θ≤55° between the first crystal structure and the second crystal structure by the X-ray diffraction (XRD) peak resolution method using CuKα radiation as a radiation source.

13. A method for producing a reflective mask for EUV lithography, comprising: forming an opening pattern by patterning an absorption film in a reflective mask blank for EUV lithography produced by the method for producing a reflective mask blank for EUV lithography according to claim 12.
